(19) United States
(12) Patent Application Publication
(10) Pub. No.: US 2009/0058288 A1
(43) Pub. Date: Mar. 5, 2009

(54) ILLUMINATION DEVICE

(75) Inventors: Dietrich Bertram, Aachen (DE); Lingli Wang, Heeze (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., Eindhoven (NL)

(21) Appl. No.: 12/282,406

(22) PCT Filed: Jun. 12, 2006
(86) PCT No.: PCT/IB06/51854

§ 371 Date: Sep. 10, 2008

(30) Foreign Application Priority Data
Jun. 15, 2005 (EP) 05105243.9

(51) Int. Cl. H01J 63/04

(52) U.S. Cl. 313/504; 313/503

(57) ABSTRACT

Illumination device with a light emitting layer structure (4) formed on a substrate (2) comprising at least one electroluminescent layer (42) between a first (41) and a second electrode (43) to emit light through the substrate (2), which comprises at least a first substrate area (21) to emit diffuse light (31) und at least a second substrate area (22) to emit directed light (32).

The present invention relates to an illumination device with an electroluminescent layer and a substrate arranged to emit diffuse and directed light simultaneously

Electroluminescent devices, so-called Light Emitting Diodes (LEDs), are inexpensive thin light sources. Especially organic LEDs (OLEDs) are ideal for large area illumination. LEDs can be widely used in general lighting, signaling, automotive lighting and backlighting for displays. OLEDs typically comprise one or more light emitting organic layers disposed between a reflective electrode, typically the cathode, and a transparent electrode, typically the anode, formed on a transparent substrate. The light emitting organic layer emits light upon application of a voltage across the electrodes. The typically emitted diffuse light of an OLED is convenient for some applications such as office illumination, but it is a disadvantage for instance for spot lighting, floodlight or desk lighting.

Present conventional floodlight or spotlight lamps place curved reflectors and/or lenses around a small conventional lighting source to direct the light. These reflectors and lenses are expensive, may be heavy and take considerable space. Document US 2004/0042198 discloses a non-pixilated organic light emitting device including a lenslet array located on an organic LED substrate to concentrate the passing light into a desired direction, which could be applied as a directed light source.

However, there is no light source available for emitting diffuse and directed light simultaneously, e.g. an integrated illumination device with a single light source for illuminating rooms and desks simultaneously.

The objective of the present invention is to provide an illumination device with a single light source arranged to emit diffuse and directed light simultaneously.

This object is achieved by an illumination device with a light emitting layer structure formed on a substrate comprising at least one electroluminescent layer between a first and a second electrode to emit light through the substrate, which comprises at least a first substrate area to emit diffuse light und at least a second substrate area to emit directed light. Directed light denotes light with a distribution of the light propagation directions significantly different from a Lambert distribution, as it is the case for diffuse emitting light sources with transparent substrates. For example, directed light is light within a light beam exhibiting a focal length, light with parallel light propagation direction or slightly divergent light. Several applications, such as automotive interior illumination or home lighting, require simple, cheap and thin light sources with multi functionality enabling a large design freedom. Electroluminescent light emitting layer structures are thin light sources, where diffuse emitting and directed emitting areas can be integrated in a thin single light source with good light focusing (beam shaping) properties of the second substrate area and good room illumination properties of a diffuse emitting first substrate area.

In a preferred embodiment, the electroluminescent layer is an organic electroluminescent layer, because organic LEDs are cheap and flexible large area light sources giving a large design freedom to adapt the illumination device to different applications.

It is advantageous, if the second substrate area comprises at least one light collimating structure. A light collimating structure will transfer diffuse emitted light into directed light, where the properties of the directed light can be adapted to the application by choosing suitable dimensional properties of the light collimating structure.

It is also advantageous, if the light collimating structure is a periodic structure to obtain defined light projection properties over the whole second substrate area.

It is furthermore advantageous, if the light collimating structure provides a first focal length in opposite direction to the emission of light equal to the distance between the electroluminescent layer and the light collimating structure. A light source, in this case the electroluminescent layer, arranged at a distance of the focal length of the light collimating structure provides good light projection properties.

It is even more advantageous, if the light collimating structure provides a second focal length in light emitting direction of at least 10 cm, preferred at least 20 cm, particular preferred at least 30 cm. This second focal length provides a bright light density at distances around the second focal length required for different applications, e.g. for reading purposes or spot light illumination of objects such as pictures or sculptures.

It is particularly advantageous, if the light collimating structure comprises at least one of the light collimating structure classes such as lenses, prisms, Fresnel lenses and parabolic light collimators. These structures have projection properties suitable for a variety of desired application. Here, a parabolic light collimator denotes a three dimensional parabolic shaped mirror segment, where of the focal point of one parabolic shaped mirror side lies on the opposite parabolic shaped mirror side and vice versa. The parabolic light collimator may be filled with materials e.g. plastic or glass. A Fresnel lens is a collapsed version of a conventional lens with circular or other shape. For an example, a circular Fresnel lens comprises a multitude of concentric rings.

It is moreover advantageous, if the light collimating structure comprises parabolic light collimators and a surface of the substrate facing the light emitting layer structure provides reflecting areas between the parabolic light collimators. Here, no diffuse light will leave the second substrate area through the substrate areas between the parabolic light collimators. It will be reflected back to the reflective electrode and probably enter the parabolic light collimators after some reflections.

An illumination device is even more advantageous, if the second substrate area comprises a parabolic light collimator and, in light emitting direction on top of the parabolic light collimator, a Fresnel lens. The parabolic light collimator provides collimated light entering the Fresnel lens to obtain well-focused light with an adjustable focus length.

In a preferred embodiment, at least one of the electrodes is structured in order to adjust the emitted light of the first and second substrate areas differently. With structured electrodes, it is possible to apply different driving voltages to the electroluminescent layer areas emitting through first and second substrate areas to adapt room illumination and directed (or spotted) lighting independently.

In an even more preferred embodiment, the electroluminescent layer is arranged to emit light of a first spectral range through the first substrate area and a second spectral range different from the first spectral range through the second substrate area.

The invention will be further described with reference to examples of embodiments shown in the drawings to which, however, the invention is not restricted.

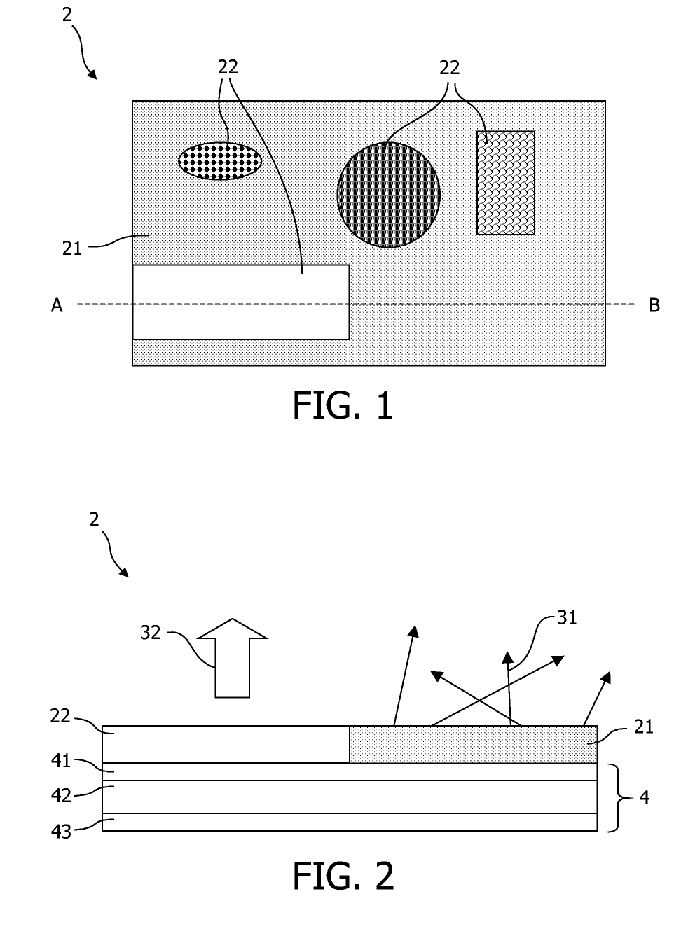

FIG. 1: top view of an illumination device according to the present invention,

FIG. 2: cross section of the illumination device according to the present invention along line A-B indicated in FIG. 1,

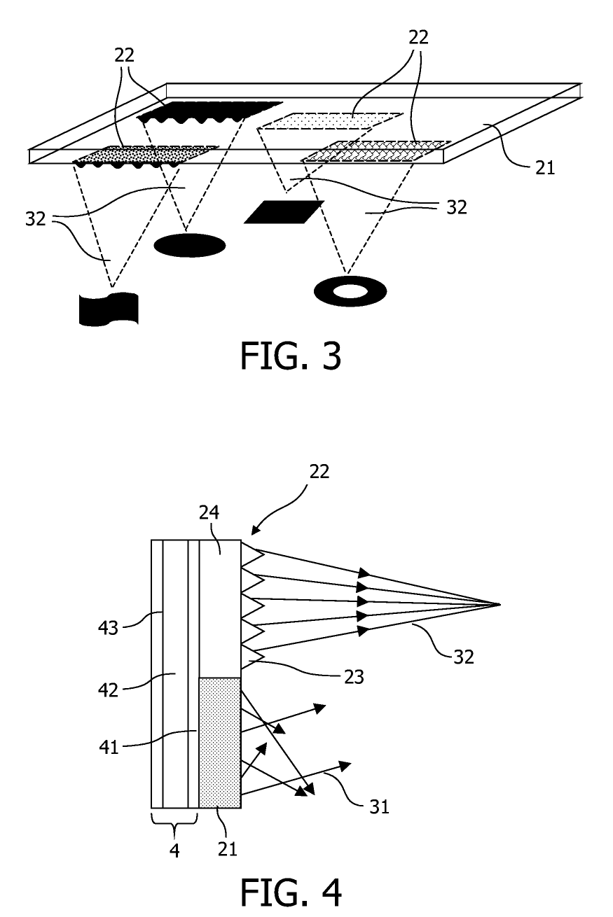

FIG. 3: side view of an illumination device according to the present invention,

FIG. 4: cross section of the illumination device according to the present invention comprising a prism array along line A-B indicated in FIG. 1,

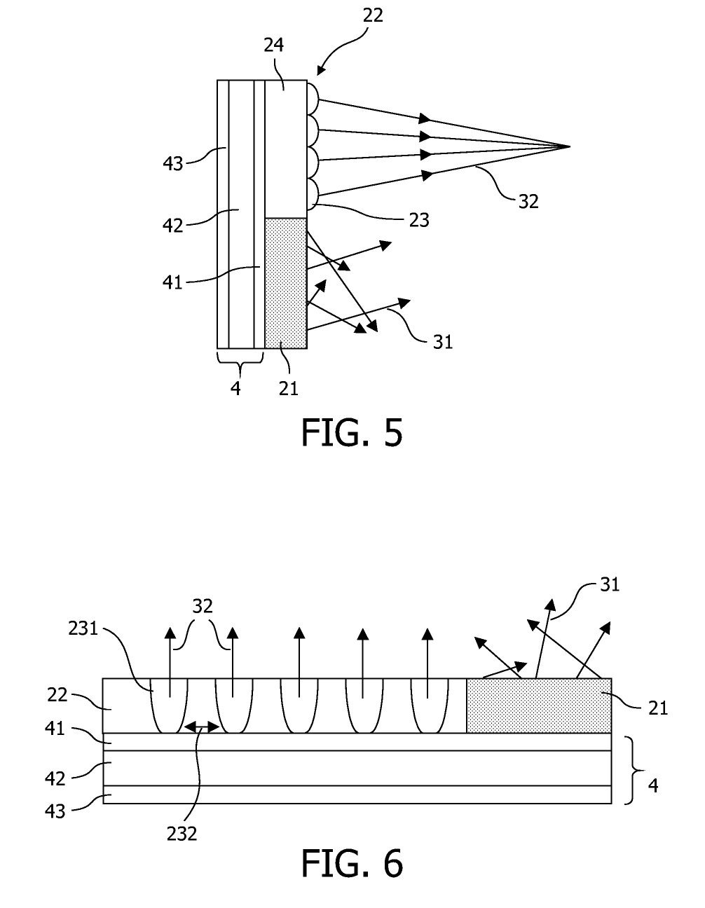

FIG. 5: cross section of the illumination device according to the present invention comprising a collecting lens array along line A-B indicated in FIG. 1,

FIG. 6: cross section of the illumination device according to the present invention comprising a parabolic light-collimating array along line A-B indicated in FIG. 1,

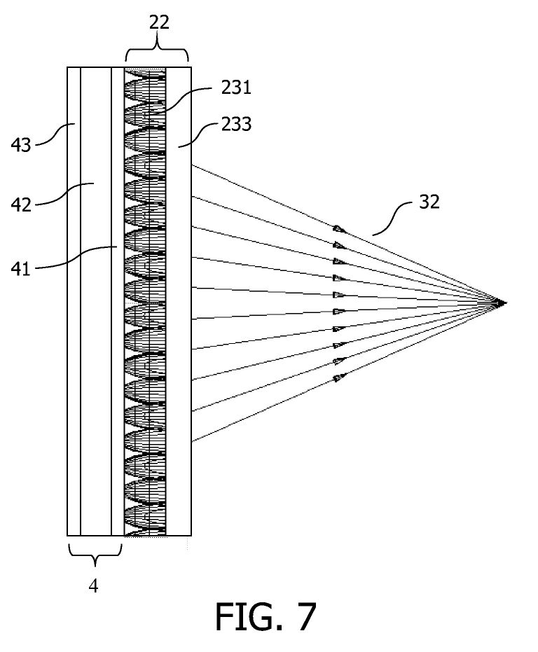

FIG. 7: cross section of the illumination device according to the present invention comprising a parabolic light collimating array and a Fresnel lens along line A-B indicated in FIG. 1.

FIG. 1 shows a top view on a substrate 2 of an illumination device according to the present comprising first substrate areas 21 to emit diffuse light as it is generated in the light emitting layer structure 4 underneath the substrate (not shown in FIG. 1). The substrate 2 consist of a transparent material, typically glass or plastic material such as PMMA or PET. The top surface at the substrate-to-air interface may be planar or may provide means to enhance the light out-coupling such as a surface structure with a certain roughness or other light out-coupling structures. Alternatively, the structure to enhance the light out-coupling can be an additional layer, typically a plastic layer, laminated on the planar top surface.

The substrate 2 of an illumination device according to the present invention (see FIG. 1) comprises at least one second substrate area 22 transferring diffuse light emitted from the light emitting layer structure 4 into directed light. The shape of the second substrate areas depend on the application conditions, it could be rectangular, circular, oval or of any other shape. The number of second substrate areas and the ratio between first and second substrate areas also depends on the application. For example, illumination devices for car interior illumination with an additional reading function comprises a large first substrate area of several tenth of square centimeters, while the second substrate area providing directed or spotted light for reading purposes could be in the order of a few square centimeters. As a second example, an integrated desk light with spot light function can be rectangular, for instance in the order of 10 cm times 100 cm with a spot light area (second substrate area) of 6 cm times 6 cm. The given sizes are only an example, for other applications the sizes may be different.

FIG. 2 shows a cross section of the illumination device along the line A-B indicated in FIG. 1. The illumination device comprises a light emitting structure 4 formed on a substrate 2. The light emitting structure 4 comprises at least one electroluminescent layer 42 between a first electrode 41, typically the transparent anode, and a second electrode 43, typically the reflective cathode, for providing electrical power to the electroluminescent layer 42. Electroluminescent light sources are generally divided into non-organic light sources (nLEDs) and organic light sources (OLEDs) by the nature of their electroluminescent layer 42. In a preferred embodiment, the electroluminescent layer 42 is an organic electroluminescent layer, because organic electroluminescent light sources (OLEDs) are cheap and flexible large area light sources giving a large design freedom to adapt the illumination device to different applications. Here the transparent electrode 41 is typically indium doped tin oxide (ITO). It is also possible to use an organic material with high electrical conductivity such as PEDT/PSS Baytron P of the company HC Starck. The material of the reflective electrode 43 is typically a metal such as aluminum, copper, silver or gold. The electrode 43 may be arranged as a homogeneous layer or may be structured, for example as a multitude of separate areas of conductive materials. Alternatively the electrode 41 can also be a homogeneous layer or can be structure.

The organic electroluminescent layer 42 may consist of light emitting polymers (PLED) or small light emitting organic molecules (SMOLED), which are embedded within an organic hole and electron conducting matrix material, for instance TCTA, TPBI or TPD doped with light emitting complexes. Light emitting structures 4 with improved efficiency may comprise a hole transporting layer such as F4-TCNQ doped MTDATA between electroluminescent layer 42 and anode 41 and a electron transporting layer such as Alq₃ or TPBI between electroluminescent layer 42 and cathode 43. There may also be electron and hole injection layers between the electrodes and the hole and electron transporting layers, respectively.

The generated light within the electroluminescent layer 4 is emitted with an isotropic light propagation distribution. Due to the refractive index difference between a typical substrate and air, the distribution of the light propagation directions of the light emitted from the illumination device exhibit a Lambert distribution. The substrate 2 according to this invention comprises at least one first substrate area 21 to emit diffuse light 31 and at least one second substrate area 22 to emit directed light 32, where the distribution of light propagation directions of light penetrating the second substrate area 22 significantly differs from a Lambert distribution as it is the case for diffuse emitting first substrate area 21, for example light within a light beam exhibiting a focal length, light with parallel light propagation direction or slightly divergent light.

FIG. 3 shows some examples of different second substrate areas 22 with different light directing properties 32. The second substrate areas may provide ring shaped, circular, square or irregular spots at a certain distance to the substrate surface.

In one embodiment, the directed light is provided by an additional layer structure. A so-called micro cavity layer structure acts a semi-transparent mirror between the anode and the substrate influencing the light propagation direction. Such an illumination devices comprising micro cavity layer structures will be emitted light preferable in a direction perpendicularly to the substrate surface, and thereby directed light.

A preferred embodiment applies a light collimating structure instead of micro cavity structure. As shown in FIG. 4, the second substrate area 22 comprises a light collimating structure 23 transferring diffuse emitted light from the electroluminescent layer 42 into directed light 32. In one embodiment, the light collimating structure 23 is incorporated into the substrate, for example by sawing, milling or other shaping technologies. In another embodiment, the light collimating structure is laminated onto a planar substrate 24 to form the second substrate area 22, as shown in FIG. 4. The light collimating structure can be manufactured for example by injection molding technologies. The properties of the directed light 32 can be adapted to the application by choosing suitable dimensional properties of the light collimating structure 23. The neighbored first substrate area 21 still emits diffuse light 31.

It is also advantageous, if the light collimating structure 23 is a periodic structure to obtain defined light projection properties such as defined focal lengths. Two examples are given in FIG. 4 and FIG. 5, where the second substrate area 22 comprises a light collimating structure 23 of an array of prisms (FIG. 4) or of an array of lenses (FIG. 5). In a preferred embodiment, the light collimating structures 23 provide a first focal length in opposite direction to the emission of light 32 equal to the distance between the electroluminescent layer 42 and the light collimating structure 23. An electroluminescent layer 42 arranged at this distance enables the light collimating structure 23 to provide an increased amount of directed light 32. It is even more advantageous, if the light collimating structure 23 provides a second focal length in light emitting direction 32 of at least 10 cm, preferred at least 20 cm, particular preferred at least 30 cm. This second focal length provides bright light for different applications, e.g. for reading purposes or spot light illumination of objects such as pictures or sculptures.

FIG. 6 shows an advantageous embodiment, where the light collimating structure 23 is not laminated onto a planar substrate 24, as shown in the previous figures. Here, the light collimating structure 23 consists of an array of parabolic light collimators 231 with a distance 232 between neighbored parabolic light collimators 231. The given dimensions may vary for different applications. The name, parabolic light collimator (PLC), derives from the fact that the PLC comprises two parabolic mirror segments, which may be filled with materials e.g. plastic or glass, with different focal points, indicated as parabolic lines in FIG. 6. The focal point of the left parabola of each PLC 231 in the cross section shown in FIG. 6 lies on the right parabola and vice versa. The two parabolic surfaces are symmetrical with respect to the axis perpendicular to the surface of the second substrate area 22. The distribution of the light propagation directions will be transferred from a broad distribution before entering the parabolic light collimators 231 into a much more forward directed light propagation after leaving the parabolic light collimators 231 leading to a directed light emission 32 of the second substrate area 22. To enhance the amount of forward directed light, the surface of the substrate 22 facing the light emitting layer structure 4 provides reflecting areas 232 between the parabolic light collimators 231. No diffuse light will leave the second substrate area 22 through the substrate areas 232 between the parabolic light collimators 231. It will be reflected back to the reflective electrode 43 and probably enter the parabolic light collimators 231 after some reflections.

A particularly advantageous embodiment is shown in FIG. 7, where the second substrate area 22 comprises an array of parabolic light collimators 231 and a Fresnel lens 233, arranged on top of the parabolic light collimators seen in light emitting direction 32. The parabolic light collimators 231 transfer the diffuse light, emitted from the electroluminescent layer 42 into mainly parallel-directed light with a narrow light propagation distribution around the axis perpendicular to the substrate surface. This light distribution will further be modified by an additional Fresnel lens 233 on top of the parabolic light collimator 231. A Fresnel lens is a collapsed version of a conventional lens comprising a multitude of concentric rings. Each ring is slightly thinner than the next and focused the light toward the center. The ridged structure can be varied in order to obtain lenses with different focal lengths transferring parallel light into focused light or divergent light into collimated light. In this embodiment, the parabolic light collimators provide collimated light, which has in first order approximation a parallel light propagation direction. It is even more advantageous, if the light collimating structure 23 provides a second focal length in light emitting direction of at least 10 cm, preferred at least 20 cm, particular preferred at least 30 cm. This second focal length provides bright light for different applications, e.g. for reading purposes or spot light illumination of objects such as pictures or sculptures. For example, thin acrylic, rigid vinyl or polycarbonate Fresnel lenses from Fresnel Technologies with thicknesses between 0.25 mm and 3.2 mm provides a second focal length between 1 cm and 61 cm. Also hexagonal or rectangular shaped Fresnel lenses as well as prism array are available. The required second focal length can be different for different applications.

In a preferred embodiment, at least one of the electrodes 41 and/or 43 is structured in order to adjust the emitted light 31, 32 of the first 21 and second substrate areas 22 differently. With structured electrodes 41 and/or 43, it is possible to apply different driving voltages to the areas of the electroluminescent layer 42 located between the structured parts of the electrode. Therefore the amount of light emitted through first substrate area 21, for example for room illumination, and through the second substrate areas 21, for example for spot light applications can be adjusted independently.

In an even more preferred embodiment, the electroluminescent layer 42 is arranged to emit light of a first spectral range through the first substrate area 21 and a second spectral range different from the first spectral range through the second substrate area 22. For example, the electroluminescent material can be varied locally. For SMOLED layers, a different doping material can be applied to the electroluminescent material for different areas of the electroluminescent layer.

The embodiments explained with reference to the figures and the description are only examples of an illumination device and should not be understood as limiting the patent claims to these examples. Alternative embodiments, which are likewise covered by the protective scope of the following patent claims, will also be possible for the person skilled in the art. The numbering of the dependent claims is not intended to imply that other combinations of the claims do not also represent advantageous embodiments.

1. Illumination device with a light emitting layer structure (4) formed on a substrate (2) comprising at least one electroluminescent layer (42) between a first (41) and a second electrode (43) to emit light through the substrate (2), which comprises at least a first substrate area (21) to emit diffuse light (31) and at least a second substrate area (22) to emit directed light (32).

2. Illumination device as claimed in claim 1, wherein the electroluminescent layer (42) is an organic electroluminescent layer.

3. Illumination device as claimed in claim 1, wherein the second substrate area (22) comprises at least one light collimating structure (23).

4. Illumination device as claimed in claim 3, wherein the light collimating structure (23) is a periodic structure.

5. Illumination device as claimed in claim 3, wherein the light collimating structure (23) provides a first focal length in opposite direction to the emission of light (32) equal to the distance between the electroluminescent layer (42) and the light collimating structure (23).

6. Illumination device as claimed in claim 3, wherein the light collimating structure (23) provides a second focal length in light emitting direction (32) of at least 10 cm, preferred at least 20 cm, particularly preferred at least 30 cm.

7. Illumination device as claimed in 3, wherein the light collimating structure (23) comprises at least one of the light collimating structure classes parabolic lenses, prisms, Fresnel lenses and parabolic light collimators.

8. Illumination device as claimed in claim 7, wherein the light collimating structure (23) comprises parabolic light collimators (231) and a surface of the substrate (2) facing the light emitting layer structure (4) provides reflecting areas (232) between the parabolic light collimators (231).

9. Illumination device as claimed in claim 7, wherein the second substrate area (22) comprises a parabolic light collimator (231) and in light emitting direction on top of the parabolic light collimator a Fresnel lens (233).

10. Illumination device as claimed in claim 1, wherein at least one of the electrodes (41, 43) is structured in order to adjust the emitted light (31, 32) of the first (21) and second substrate areas (22) differently.

11. Illumination device as claimed in claim 1, wherein the electroluminescent layer (42) is arranged to emit light of a first spectral range through the first substrate area (21) and a second spectral range different from the first spectral range through the second substrate area (22).
